(19) United States
(12) Patent Application Publication
(10) Pub. No.: US 2015/0016031 A1
(43) Pub. Date: Jan. 15, 2015

(54) PACKING PIECE AND PACKING MEMBER FORMED FROM THE PACKING PIECE

(71) Applicant: HON HAI PRECISION INDUSTRY CO., LTD., New Taipei (TW)

(72) Inventors: CHIH-TA HUANG, New Taipei (TW); MENG-HSIEN LIN, New Taipei (TW); YAO-TING CHANG, New Taipei (TW)

(73) Assignee: HON HAI PRECISION INDUSTRY CO., LTD., New Taipei (TW)

(21) Appl. No.: 13/950,524

(22) Filed: Jul. 25, 2013

(30) Foreign Application Priority Data
Jul. 8, 2013 (TW) 102124447

(51) Int. Cl. H05K 7/14

(52) U.S. Cl. CPC H05K 7/1401
USPC 361/679.01; 248/316.1; 29/505

(57) ABSTRACT

A packing member attached to non-coplanar outer surfaces of an electronic component includes a number of non-coplanar plates attached to the outer surfaces of the electronic component. A junction of every two adjacent plates defines a row of a plurality of through holes. A middle line of each row of through holes is aligned with a corresponding junction of two adjacent outer surfaces of the electronic component.

### BACKGROUND

1. Technical Field

The present disclosure relates to a packing piece attached to an electronic component.

2. Description of Related Art

Packing pieces are often attached to outer surfaces of electronic components, to isolate the electronic components from the motherboards. However when a packing piece is bent, stress is generated at the bend, thus the packing piece cannot completely contact the electronic component. As a result, the packing piece can disengage from the electronic component by air or vibrations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an embodiment of a packing sheet.

FIG. 2 is an exploded, isometric view of an embodiment of a packing member formed from the packing sheet of FIG. 1, together with an electronic component.

FIG. 3 is an assembled, isometric view of FIG. 2.

FIG. 4 an inverted view of FIG. 3.

FIG. 5 is a flowchart of an embodiment of a method for manufacturing a packing member.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

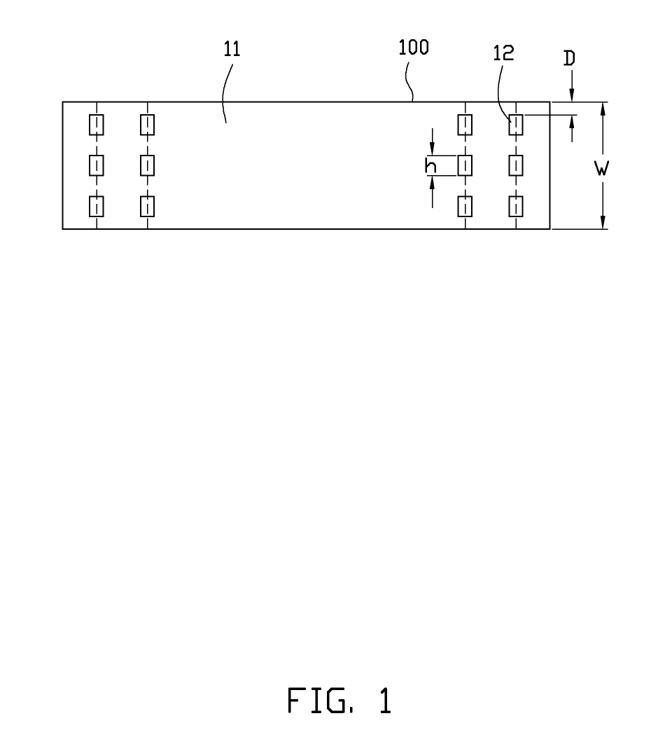

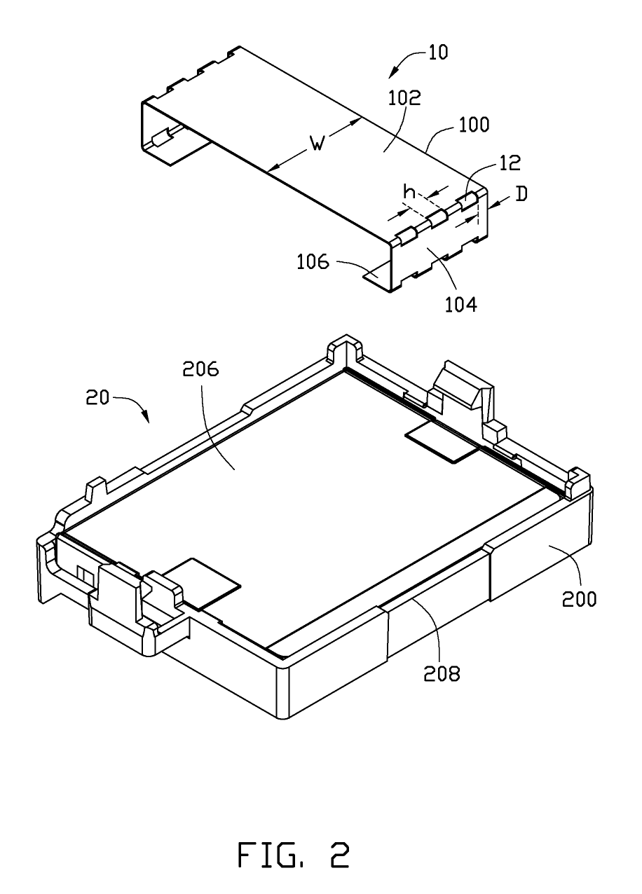

FIGS. 1 and 2 show one embodiment of a packing piece made from a flat and rectangular sheet 11 of Mylar and defining four rows of a plurality of through holes 12. The sheet 11 is capable of being bent along the rows of through holes 12 to form a packing member 10 used to attach to non-coplanar outer surfaces of a rectangular electronic component 20, such as a power supply.

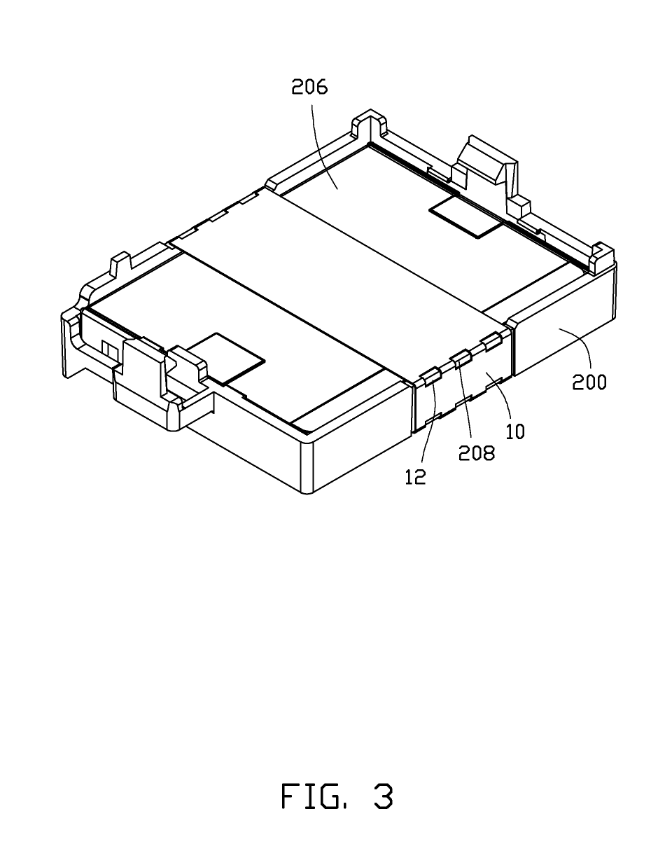

The outer surfaces of the electronic component 20 include a top wall 206, a bottom wall 204 (shown in FIG. 3) opposite to the top wall 206, and two sidewalls 200 connected between sides of the top wall 206 and the bottom wall 204. A junction 208 is formed between each sidewall 200 and each of the top and bottom walls 206 and 204.

Two rows of through holes 12 are adjacent to an end of the sheet 11, and the other two rows of through holes 12 are adjacent to an opposite end of the sheet 11. A width of the sheet 11 is defined as w. Each row of through holes 12 extends along the widthwise direction of the sheet 11 perpendicular to opposite side edges 100 of the sheet 11. A number of each row of through holes 12 is defined as n. A distance between each side edge 100 of the sheet 11 and an adjacent end wall bounding an adjacent outmost through hole 12 of each row of through holes 12 is defined as D. In the embodiment, D>w/10. A length of each through hole 12 in the widthwise direction of the sheet 11 is defined as h. In the embodiment, h<w/5, and n*h≦w/2. The packing member 10 includes a top plate 102, two end plates 104 perpendicularly extending down from opposite ends of the top plate 102, and two bottom plates 106 perpendicularly extending toward each other from bottom sides of the end plates 104. Each row of through holes 12 is located at a junction between each end plate 104 and each of the top plate 102 and the bottom plate 106.

In this embodiment, the through holes 12 are rectangular, and extend in the widthwise direction of the packing member 10. In another embodiment, the through holes 12 can be other shapes.

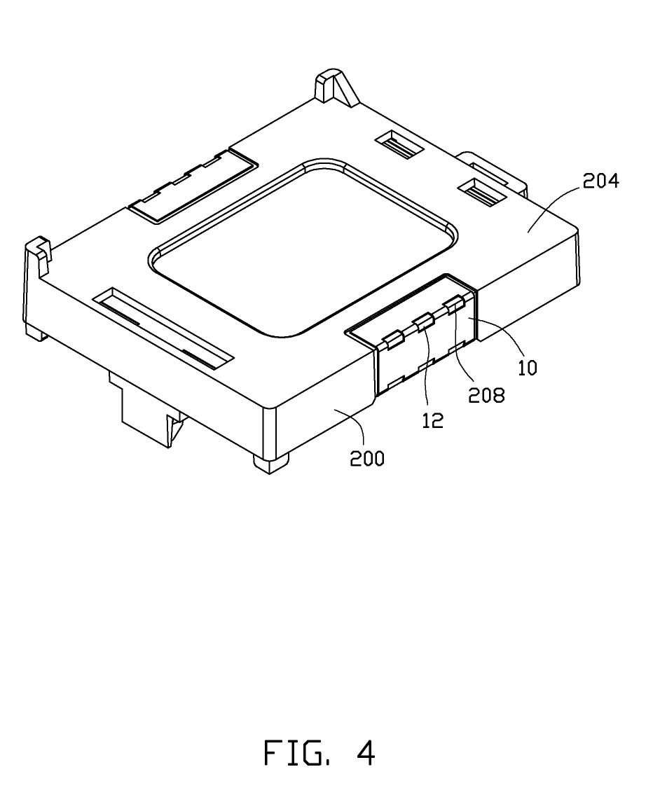

FIGS. 3 and 4 show that in use, the sheet 11 is attached to the top wall 206. Two inner rows of through holes 12 are aligned with the junctions 208 between the top wall 206 and the sidewalls 200. The sheet 11 is bent down along the inner rows of through holes 12. A portion of the sheet 11 between the two rows of through holes 12 of each end of the sheet 11 is attached to a corresponding sidewall 200. Two outmost rows of through holes 12 at the ends of the sheet 11 align with the junction 208 between the sidewalls 200 and the bottom wall 204. Opposite ends of the sheet 11 are bent toward each other along the outmost rows of through holes 12. Therefore, the top plate 102 contacts the top wall 206. The end plates 104 contact the corresponding sidewalls 200, and the bottom plates 106 contact opposite sides of the bottom wall 204. A middle line of each row of through holes 12 aligns with a corresponding junction 208.

Because the packing member 10 has through holes 12 aligning with the junction 208, the junction of the packing piece 10 will not be rigid. Therefore, the packing member 10 can be easily and firmly attached to the electronic component 20.

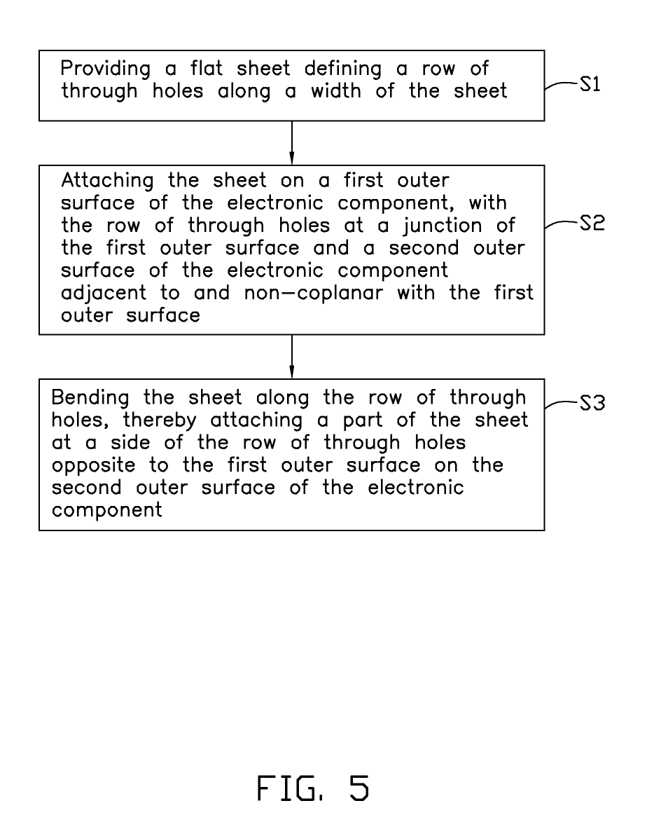

FIG. 5 shows that a method for manufacturing the packing member 10 includes the following steps.

In step S1, a packing piece defining a row of through holes 12 extending along a widthwise direction of the packing piece is provided. A width of the packing piece is defined as w. The row of through holes 12 extends along the widthwise direction of the packing piece perpendicular to opposite side edges 100 of the packing piece. A number of the row of through holes 12 is defined as n. A distance between each side edge 100 of the packing piece and an adjacent wall bounding an adjacent outmost through hole 12 of the row of through holes 12 is defined as D. In the embodiment, D>w/10. A length of each through hole 12 in the widthwise direction of the packing piece is defined as h. In the embodiment, h<w/5, and n*h≦w/2.

In step S2, the packing piece is attached on a first surface 206 of an electronic component 20, with the row of through holes 12 locating at a junction 208 between the first outer surface 206 and a second outer surface 200 of the electronic component 20 adjacent to the first outer surface 206.

In step S3, the packing piece is formed along a portion defining the row of through holes 12. Therefore, a part of the packing piece at a side of the row of through holes 12 opposite to the first surface 206 is attached on the second outer surface 200.

It is believed that the present embodiments and their advantages will be understood from the foregoing description, and various changes may be made thereto without departing from the spirit and scope of the description or sacrificing all of their material advantages, the examples hereinbefore described merely being embodiments.

What is claimed is:

1. A packing piece comprising a flat sheet defining a row of through holes, wherein the sheet is capable of being bent along the row of through holes.

2. The packing piece of claim 1, wherein a width of the packing piece between two opposite side edges of the packing piece perpendicular to the row of through holes is defined as w, a distance between each side edge and an adjacent end wall bounding an adjacent outmost through hole of the row of through holes is defined as D, and D>w/10.

3. The packing piece of claim 1, wherein a width of the packing piece between two opposite side edges of the packing piece perpendicular to the row of through holes is defined as w, and a length of each through hole in a widthwise direction of the packing piece is defined as h, and h<w/5.

4. The packing piece of claim 1, wherein a width of the packing piece between two opposite side edges of the packing piece perpendicular to the row of through holes is defined as w, a length of each through hole in a widthwise direction of the packing piece is defined as h, a number of the row of through holes is defined as n, and n*h≦w/2.

5. A packing member, comprising a plurality of non-coplanar plates attached to corresponding outer surfaces of an electronic component, wherein a junction between every two adjacent plates defines a row of through holes.

6. The packing member of claim 5, wherein a width of the packing member in a direction of the row of through holes is defined as w, a distance between each side edge perpendicular to a width direction of the packing member and an adjacent end wall bounding an adjacent outmost through hole of the row of through holes is defined as D, and D>w/10.

7. The packing member of claim 5, wherein a width of the packing member in a direction of the row of through holes is defined as w, a length of each through hole in a widthwise direction of the packing piece is defined as h, and h<w/5.

8. The packing member of claim 5, wherein a width of the packing member in a direction of the row of through holes is defined as w, a length of each through hole in a widthwise direction of the packing piece is defined as h, a number of the row of through holes is defined as n, and n*h≦w/2.

9. A method for manufacturing a packing member to be attached to an electronic component, the method comprising:
providing a flat sheet defining a row of through holes along a width of the sheet;
attaching the sheet on a first outer surface of the electronic component, with the row of through holes at a junction of the first outer surface and a second outer surface of the electronic component adjacent to and non-coplanar with the first outer surface; and
bending the sheet along the row of through holes, thereby attaching a part of the sheet at a side of the row of through holes opposite to the first outer surface on the second outer surface of the electronic component.

10. The method of claim 9, wherein a middle line of the row of through holes is aligned with the junction of the electronic component.
